(19) United States
(12) Patent Application Publication
(10) Pub. No.: US 2026/0128741 A1
(43) Pub. Date: May 7, 2026

(54) RECEIVER CIRCUIT WITH PARALLEL TRIGGER CIRCUITRY

(71) Applicant: TEXAS INSTRUMENTS INCORPORATED, Dallas, TX (US)

(72) Inventors: Sneha Shetty, Bengaluru (IN); Rajesh Yadav, Bengaluru (IN)

(21) Appl. No.: 18/938,447

(22) Filed: Nov. 6, 2024

(51) Int. Cl. H03K 17/687; H03K 19/0175

(52) U.S. Cl. CPC H03K 17/6872; H03K 19/017509

(57) ABSTRACT

Receiver circuits, integrated circuits containing such receiver circuits, and related methods are described. For example, a receiver circuit includes first trigger circuitry configured with a first trigger level for a low-to-high transition of an input signal applied to an input node of the receiver circuit, and second trigger circuitry arranged at least in part in parallel with the first trigger circuitry and configured with a second trigger level for a high-to-low transition of the input signal, the second trigger level being different than the first trigger level. Respective inputs of the first and second trigger circuitry are coupled to the input node of the receiver circuit and respective outputs of the first and second trigger circuitry are coupled to an output node of the receiver circuit.

### TECHNICAL FIELD

The present disclosure relates to the field of electronic circuits and systems, and more particularly, but not exclusively, to receiver circuits.

### BACKGROUND

Receiver circuits are illustratively utilized as part of input/output (I/O) circuitry in an integrated circuit, and in numerous other applications. Such receiver circuits in some applications receive input signals from other integrated circuits and/or from other external components of an electronic system.

### SUMMARY

The present disclosure describes receiver circuits with parallel trigger circuitry, as well as integrated circuits containing such receiver circuits, and related methods.

This summary is not an extensive overview of the disclosure. Rather, a purpose of the summary is to present some examples of the present disclosure in a simplified form as a prelude to a more detailed description that is presented later.

In some examples, a receiver circuit includes first trigger circuitry configured with a first trigger level for a low-to-high transition of an input signal applied to an input node of the receiver circuit, and second trigger circuitry arranged at least in part in parallel with the first trigger circuitry and configured with a second trigger level for a high-to-low transition of the input signal, the second trigger level being different than the first trigger level. Respective inputs of the first and second trigger circuitry are coupled to the input node of the receiver circuit and respective outputs of the first and second trigger circuitry are coupled to an output node of the receiver circuit.

In some other examples, an integrated circuit comprises a plurality of receiver circuits, and additional circuitry coupled to the plurality of receiver circuits. At least one of the receiver circuits comprises first trigger circuitry configured with a first trigger level for a low-to-high transition of an input signal applied to an input node of the receiver circuit, and second trigger circuitry arranged at least in part in parallel with the first trigger circuitry and configured with a second trigger level for a high-to-low transition of the input signal, the second trigger level being different than the first trigger level. Respective inputs of the first and second trigger circuitry are coupled to the input node of the receiver circuit and respective outputs of the first and second trigger circuitry are coupled to an output node of the receiver circuit.

In some additional examples, a method of manufacturing an integrated circuit comprises forming a plurality of receiver circuits, and forming additional circuitry, wherein the receiver circuits are coupled to the additional circuitry, and wherein forming each of one or more of the receiver circuits comprises forming first trigger circuitry configured with a first trigger level for a low-to-high transition of an input signal applied to an input node of the receiver circuit, and forming second trigger circuitry arranged at least in part in parallel with the first trigger circuitry and configured with a second trigger level for a high-to-low transition of the input signal, the second trigger level being different than the first trigger level. Respective inputs of the first and second trigger circuitry are coupled to the input node of the receiver circuit, and respective outputs of the first and second trigger circuitry are coupled to an output node of the receiver circuit.

### BRIEF DESCRIPTION OF THE DRAWINGS

FIG. 1 shows a receiver circuit with parallel trigger circuitry in accordance with examples of the present disclosure;

FIG. 2 is a block diagram of an integrated circuit that includes a plurality of receiver circuits and additional circuitry in accordance with examples of the present disclosure;

FIG. 3 is a schematic diagram of an implementation of the FIG. 1 receiver circuit in accordance with examples of the present disclosure;

FIGS. 4 and 5 are timing diagrams illustrating operation of a receiver circuit with parallel trigger circuitry in accordance with examples of the present disclosure;

FIG. 6 shows another receiver circuit with parallel trigger circuitry in accordance with examples of the present disclosure, in which Schmitt trigger circuits are utilized in the parallel trigger circuitry;

FIG. 7 is a flow diagram illustrating a method of operating a receiver circuit in accordance with examples of the present disclosure; and

FIG. 8 is a flow diagram illustrating a method of manufacturing an integrated circuit comprising a plurality of receiver circuits in accordance with examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein, such as transistors and other semiconductor-based circuitry, or portions and combinations thereof, can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

In some examples, a receiver circuit comprises parallel trigger circuitry as described herein. For example, such a receiver circuit is illustratively configured to operate on an I/O supply voltage (VDDIO) of about 1.2 volts (1.2V) while also being configured to handle a 5 volt (5V) input signal. The receiver circuit in such an example provides 1.2V compliant trigger levels for low-to-high transition input voltage (VIH) and high-to-low transition input voltage (VIL) with an appropriate amount of hysteresis (e.g., at least 50 mV of hysteresis), while also drawing negligible static current from the 5V input signal. Accordingly, some examples provide a receiver circuit which is capable of reliably receiving a 5V switching signal while being compliant with 1.2V VIH/VIL levels, and meeting a 50 mV hysteresis requirement, all without drawing significant static current. Other input signal voltages, supply voltages, VIH/VIL trigger levels and static current performance can be utilized in other examples.

These and other examples provide technical solutions to significant problems of alternative approaches. For example, one or more such examples overcome significant challenges that can otherwise arise in attempting to configure a receiver circuit to operate at relatively low VDDIO supply voltage levels (e.g., 1.2V) while also accommodating relatively high input signal swings (e.g., 5V), and providing desired amounts of hysteresis (e.g., 50 mV) at low static current. While various described examples may be expected to provide such or similar improvements, no particular result is a requirement of the present disclosure unless explicitly recited in a particular claim.

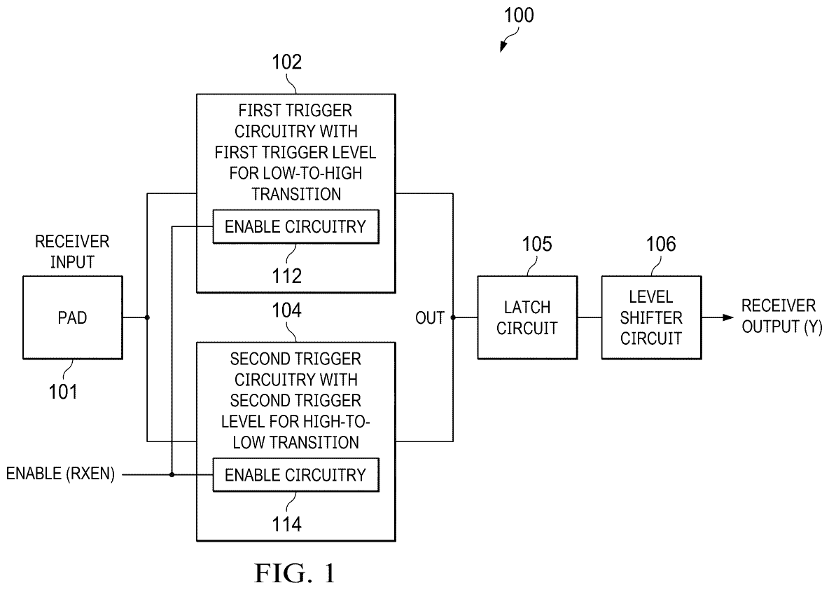

Referring now to FIG. 1, a receiver circuit 100 is configured to receive an input signal applied to an input pad 101. The input pad 101, also denoted herein as simply PAD, represents the receiver input of the receiver circuit 100 in this example. An input signal applied to the input pad 101 is also denoted in some examples herein as a receiver input PAD, to refer to a signal applied to the input pad 101. The input pad 101 is an example of what is more generally referred to herein as an “input node” of the receiver circuit 100. The receiver circuit 100 comprises first trigger circuitry 102 and second trigger circuitry 104, which are arranged in parallel with one another as illustrated. The first trigger circuitry 102 is configured with a first trigger level for a low-to-high transition of an input signal applied to the input pad 101 of the receiver circuit 100, and the second trigger circuitry 104 is configured with a second trigger level for a high-to-low transition of the input signal applied to the input pad 101, with the second trigger level being different than the first trigger level (e.g., lower than the first trigger level).

In some examples, the first trigger level provided by the first trigger circuitry 102 more particularly comprises a VIH trigger level for the receiver circuit 100 and the second trigger level provided by the second trigger circuitry 104 more particularly comprises a VIL trigger level for the receiver circuit 100, although other types and arrangements of trigger levels can be used in other examples.

Respective inputs of the first trigger circuitry 102 and the second trigger circuitry 104 are coupled to the input pad 101 of the receiver circuit 100 and respective outputs of the first trigger circuitry 102 and the second trigger circuitry 104 are coupled to an output node of the receiver circuit 100. As illustrated, the outputs of the first trigger circuitry 102 and the second trigger circuitry 104 are coupled together at a common output node denoted OUT in FIG. 1. The common output node OUT is coupled to a receiver output Y of the receiver circuit 100 via a serial arrangement of a latch circuit 105 and a level shifter circuit 106. Each of the common output node OUT and the receiver output Y is considered an example of an “output node” of the receiver circuit 100, as that term is broadly used herein. Other types of input and output nodes and at least partially parallel arrangements of first and second trigger circuitry can be used in other examples.

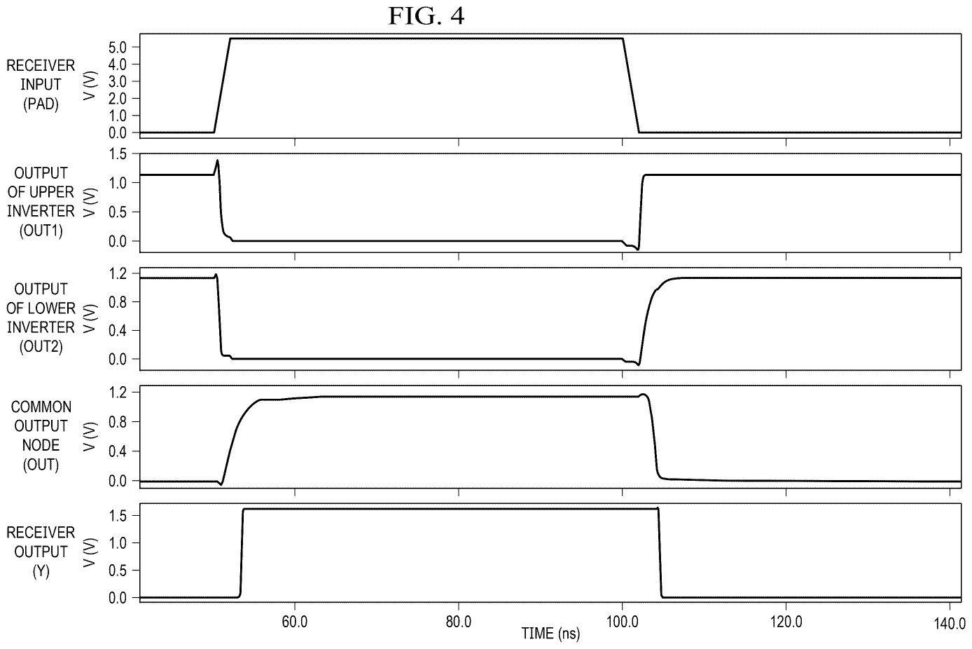

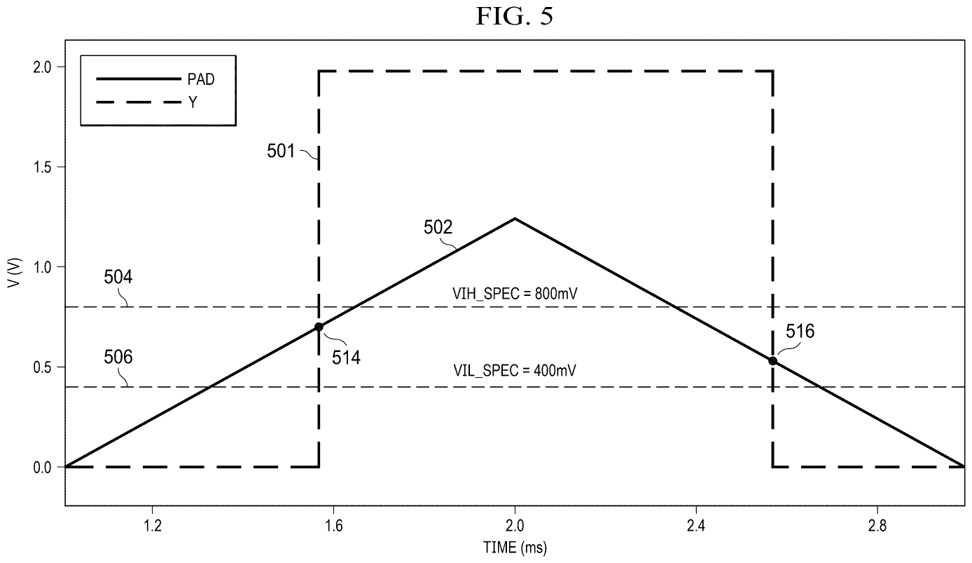

In some examples, the first trigger circuitry 102 is configured to drive an output node of the receiver circuit, such as the receiver output Y, to one of a logic high level and a logic low level responsive to the low-to-high transition of the input signal and the second trigger circuitry 104 is configured to drive the output node of the receiver circuit to the other of the logic high level and the logic low level responsive to the high-to-low transition of the input signal. Examples of such operation can be seen in the timing diagrams of FIGS. 4 and 5 to be described below.

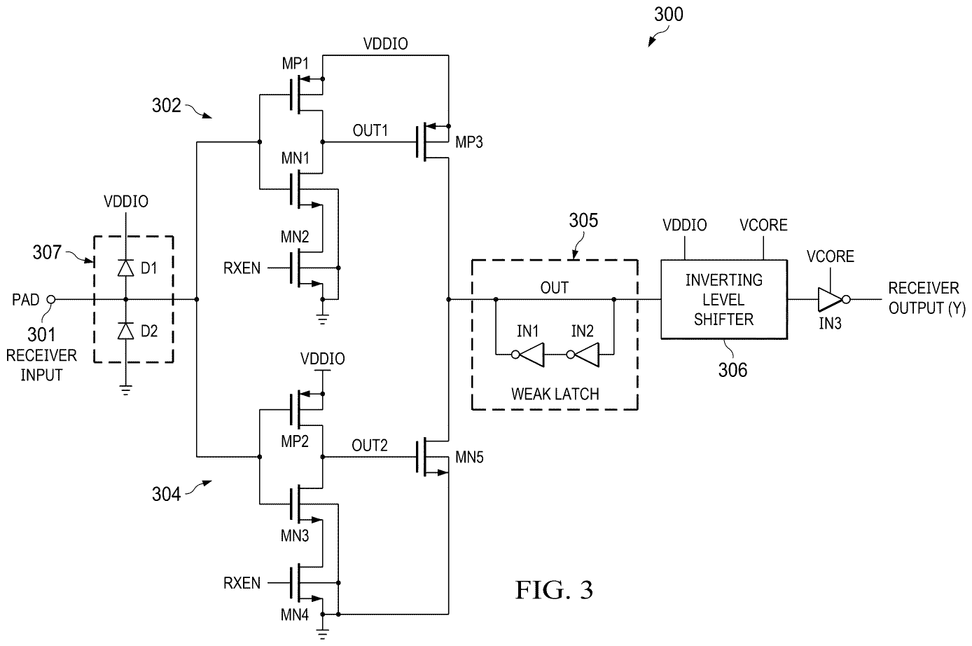

In some examples, the first and second trigger circuitry 102 and 104 comprise respective first and second inverters, not explicitly shown in FIG. 1, with each of the first and second inverters having an input coupled to the input pad 101 of the receiver circuit 100 and an output coupled to the output node OUT of the receiver circuit 100. Examples of such first and second inverters will be described in more detail below in conjunction with the schematic diagram of FIG. 3. Additional or alternative circuitry is included in the first and second trigger circuitry 102 and 104 in some examples. As a more particular illustration, other examples can configure the first and second trigger circuitry 102 and 104 to include respective first and second Schmitt trigger circuits, in place of the above-noted first and second inverters.

The first and second trigger circuitry 102 and 104 further comprise respective enable circuitry 112 and 114. The enable circuitry 112 and 114, which is an example of what is more generally referred to herein as control circuitry, is configured to concurrently enable the first and second trigger circuitry 102 and 104 responsive to an applied control signal. The applied control signal in this example is implemented as an enable signal, also denoted as a receiver enable (RXEN) signal.

The enable signal is an example of what is more generally referred to herein as a “control signal.” That term as broadly used herein is intended to encompass any of a wide variety of different types and arrangements of one or more enable signals as well as additional or alternative signals or combinations of multiple signals that may be used to concurrently activate and deactivate the first trigger circuitry 102 and second trigger circuitry 104 of the receiver circuit 100. Although the control circuitry comprising enable circuitry 112 and 114 is illustratively shown as being implemented in its entirety within the respective first and second trigger circuitry 102 and 104 in the example of FIG. 1, in other examples such circuitry may be implemented at least in part externally to the first and second trigger circuitry 102 and 104.

The outputs of the first trigger circuitry 102 and the second trigger circuitry 104 that are coupled together at common output node OUT are also coupled to an input of the latch circuit 105. An output of the latch circuit 105 is coupled to an input of the level shifter circuit 106. The latch circuit 105 and level shifter circuit 106 are therefore coupled in series between the outputs of the first and second trigger circuitry 102 and 104 and the receiver output Y, and thereby couple the common output node OUT to the output node corresponding to receiver output Y.

The latch circuit 105 in some examples illustratively comprises a serial arrangement of multiple invertors, not explicitly shown in FIG. 1, with an input of a first one of the multiple inverters being coupled to the outputs of the respective first and second trigger circuitry 102 and 104, with an output of the first one of the multiple inverters being coupled to an input of another one of the multiple inverters, and an output of the other one of the multiple inverters being coupled to the outputs of the first and second trigger circuitry. Other types and arrangements of one or more latch circuits can be used in other examples. In some of these examples, the latch circuit 105 is more particularly implemented as a “weak” latch, additional examples of which will be described in more detail below in conjunction with the schematic diagram of FIG. 3.

The level shifter circuit 106 in some examples may be an inverting level shifter or a non-inverting level shifter, and can be implemented in accordance with one or more examples disclosed in U.S. Pat. No. 10,848,156, issued Nov. 24, 2020 and entitled “Voltage Level Shifter,” which is commonly assigned herewith and incorporated by reference herein in its entirety. Other types and arrangements of one or more level shifter circuits can be used in other examples.

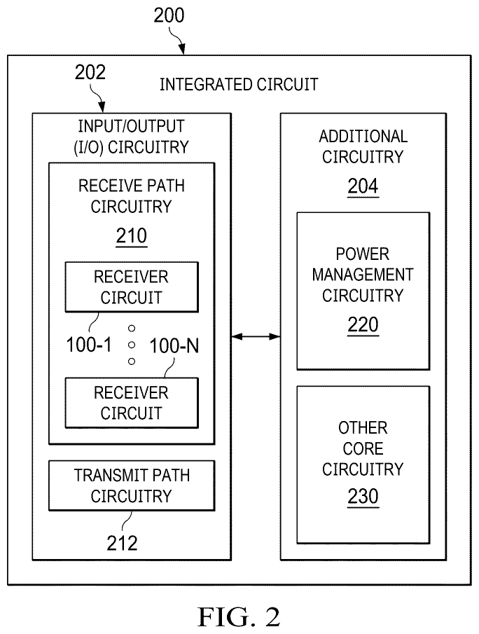

The receiver circuit 100 is illustratively implemented as part of an integrated circuit, examples of which will now be described in more detail with reference to FIG. 2. In other examples, the receiver circuit 100 can be implemented in other ways, such as at least partially in the form of discrete circuit components.

Referring now to FIG. 2, an example integrated circuit 200 is shown. The integrated circuit 200 comprises a plurality of receiver circuits 100-1 through 100-N, each of which is illustratively configured in the manner previously described in conjunction with FIG. 1. The variable N denotes a positive integer greater than one, which may vary depending upon the particular implementation, and in some examples can take on values such as 2, 10, 100, etc. Other types and arrangements of receiver circuits, including one or more receiver circuits configured in a manner different than that illustrated in FIG. 1, can be included in the integrated circuit 200.

The integrated circuit 200 includes input/output (I/O) circuitry 202 and additional circuitry 204 coupled to the I/O circuitry 202. The I/O circuitry 202 further comprises receive path circuitry 210 and transmit path circuitry 212, with the receiver circuits 100-1 through 100-N being implemented as part of the receive path circuitry 210. The additional circuitry 204 in this example includes power management circuitry 220 and other core circuitry 230. A wide variety of other types and arrangements of circuitry can be implemented within the integrated circuit 200, in addition to the receiver circuits 100-1 through 100-N.

In some examples, at least a subset of the receiver circuits 100-1 through 100-N receive input signals from one or more external devices and/or or systems, not shown in FIG. 2, relating to power management functionality of the integrated circuit 200, for further processing by the power management circuitry 220. Additional or alternative input signals of a wide variety of different types may additionally or alternatively be received by at least portions of the receiver circuits 100-1 through 100-N from one or more external devices and/or systems for further processing by the other core circuitry 230. The transmit path circuitry 212 of the I/O circuitry 202 illustratively comprises a plurality of transmitter circuits, not explicitly shown, for providing output signals, resulting from processing performed in the additional circuitry 204, from the integrated circuit 200 to the one or more external devices and/or systems. Numerous other integrated circuits can be configured to include one or more receiver circuits of the type previously described in conjunction with FIG. 1.

FIG. 3 shows an example receiver circuit 300 which illustrates an implementation of the example receiver circuit 100 of FIG. 1. The receiver circuit 300 comprises an input node 301 denoted PAD and a receiver output denoted Y. The receiver circuit 300 further comprises first trigger circuitry 302 configured with a first trigger level for a low-to-high transition of an input signal applied to the input node 301 of the receiver circuit 300, and second trigger circuitry 304 arranged at least in part in parallel with the first trigger circuitry 302 and configured with a second trigger level for a high-to-low transition of the input signal, with the second trigger level being different than the first trigger level (e.g., lower than the first trigger level). Respective inputs of the first and second trigger circuitry 302 and 304 are coupled to the input node 301 of the receiver circuit 300 and respective outputs of the first and second trigger circuitry 302 and 304 are coupled to an output node of the receiver circuit 300, illustratively the common output node OUT. The common output node OUT is coupled to another output node of the receiver circuit 300, namely, the receiver output Y, via a latch circuit 305 comprising inverters IN1 and IN2, an inverting level shifter 306, and an additional inverter IN3.

The receiver circuit 300 further includes, between the input node 301 and the inputs of the first and second trigger circuitry 302 and 304, a protective circuit 307 illustratively comprising a serial arrangement of first and second diodes D1 and D2 as shown. The two diodes D1 and D2 are coupled in series between a lower supply terminal, illustratively a ground terminal in the present example, and an upper supply terminal, illustratively a VDDIO supply terminal in the present example, with an anode of the upper diode D1 coupled to a cathode of the lower diode D2 and to the input node 301, a cathode of the upper diode D1 coupled to the VDDIO supply terminal, and an anode of the lower diode D2 coupled to the ground terminal. The two diodes D1 and D2 of the protective circuit 307 serve to limit excessive positive and negative voltages at the input node 301 relative to VDDIO and ground, respectively, in the event of, for example, an electrostatic discharge (ESD) event at the input node 301. Such diodes are illustratively implemented as respective PN junction diodes with threshold voltages of about 0.7V, although other types and arrangements of one or more diodes, as well as other types of protective circuits, can be used in other examples. For example, additional or alternative protective circuits including charged device model (CDM) protective circuits of various types can be used for protective circuit 307.

The first and second trigger circuitry 302 and 304 comprise respective first and second inverters, with each of the first and second inverters having an input coupled to the input node 301 of the receiver circuit 300 and an output coupled to the common output node OUT of the receiver circuit 300.

The respective first and second inverters of the first and second trigger circuitry 302 and 304 in this example are each implemented using a P-type field effect transistor (FET) and an N-type FET, each having gate, source and drain terminals, and more particularly as P-type and N-type metal-oxide-semiconductor (MOS) FETs, also referred to herein as PMOS and NMOS devices, which are illustratively configured in accordance with a complementary MOS (CMOS) arrangement. Other types and arrangements of transistors can be used to implement the first and second inverters in other examples.

The first inverter of the first trigger circuitry 302 comprises PMOS device MP1 and NMOS device MN1. The output of the first inverter is denoted OUT 1. The first trigger circuitry 302 further comprises enable circuitry implemented by NMOS device MN2.

Similarly, the second inverter of the second trigger circuitry 304 comprises PMOS device MP2 and NMOS device MN3. The output of the second inverter is denoted OUT2. The second trigger circuitry 304 further comprises enable circuitry implemented by NMOS device MN4.

The gate terminals of MP1 and MN1 of the first inverter of first trigger circuitry 302 are coupled to the input node 301 of the receiver circuit 300, the source terminal of MP1 is coupled to an upper supply terminal of the receiver circuit 300, illustratively a VDDIO supply terminal in the present example, the drain terminal of MP1 is coupled to the drain terminal of MN1, and the source terminal of MN1 is coupled to a lower supply terminal of the receiver circuit 300, illustratively a ground terminal in the present example, via the enable circuitry of the first trigger circuitry 302. More particularly, in the enable circuitry of the first trigger circuitry 302, the gate terminal of MN2 is coupled to an enable signal RXEN, the drain terminal of MN2 is coupled to the source terminal of MN1, and the source terminal of MN2 is coupled to the ground terminal.

Similarly, the gate terminals of MP2 and MN3 of the second inverter of second trigger circuitry 304 are coupled to the input node 301 of the receiver circuit 300, the source terminal of MP2 is coupled to the VDDIO supply terminal, the drain terminal of MP2 is coupled to the drain terminal of MN3, and the source terminal of MN3 is coupled to the ground terminal via the enable circuitry of the second trigger circuitry 304. More particularly, in the enable circuitry of the second trigger circuitry 304, the gate terminal of MN4 is coupled to the enable signal RXEN, the drain terminal of MN4 is coupled to the source terminal of MN3, and the source terminal of MN4 is coupled to the ground terminal.

The first trigger circuitry 302 further comprises an additional PMOS device MP3 having a gate terminal coupled to the respective drain terminals of MP1 and MN1 of the first inverter at the output OUT1, a source terminal coupled to the VDDIO supply terminal, and a drain terminal coupled to the common output node OUT of the receiver circuit 300.

Similarly, the second trigger circuitry 304 further comprises an additional NMOS device MN5 having a gate terminal coupled to the respective drain terminals of MP2 and MN3 of the second inverter at the output OUT2, a source terminal coupled to the ground terminal, and a drain terminal coupled to the common output node OUT of the receiver circuit 300.

The enable circuity comprising MN2 in the first trigger circuitry 302 and MN4 in the second trigger circuitry 304 is an example of what is more generally referred to herein as “control circuitry” of the receiver circuit 300. Such control circuitry is generally configured to concurrently enable the first and second trigger circuitry 302 and 304 responsive to an applied control signal, illustratively the enable signal RXEN in the present example. Other types and arrangements of control circuitry can be used to enable the first and second trigger circuitry 302 and 304, possibly responsive to other types of control signals, in other examples. As indicated above, in typical operation of some examples, both the first and second trigger circuitry 302 and 304 are enabled together, although other operating modes are possible in other examples.

While enabled, the first trigger circuitry 302 is configured to drive an output node of the receiver circuit 300 to one of a logic high level and a logic low level responsive to the low-to-high transition of the input signal applied to input node 301, and the second trigger circuitry 304 is configured to drive the output node of the receiver circuit 300 to the other of the logic high level and the logic low level responsive to the high-to-low transition of the input signal applied to the input node 301. More particularly, in the present example, the first trigger circuitry 302 is configured to drive the common output node OUT and thereby the receiver output Y to a logic high level responsive to the low-to-high transition of the input signal applied to input node 301, and the second trigger circuitry 304 is configured to drive the common output node OUT and thereby the receiver output Y to a logic low level responsive to the high-to-low transition of the input signal applied to input node 301.

In some examples, channel sizes of respective PMOS and NMOS devices MP1 and MN2 of the first inverter of the first trigger circuitry 302 are configured in a first ratio that at least partially sets the first trigger level, and channel sizes of respective PMOS and NMOS devices MP2 and MN3 of the second inverter are configured in a second ratio, different than the first ratio, that at least partially sets the second trigger level. For example, the first ratio may be approximately 5:1 and the second ratio may be approximately 1:1, such that the PMOS:NMOS channel size ratio of the first inverter is MP1:MN1=5:1 and the PMOS:NMOS channel size ratio of the second inverter MP2:MN3=1:1, although numerous other ratio values can be used in other examples.

With regard to above-noted sizing of the inverter transistors in the first and second trigger circuitry 302 and 304, relative adjustments in channel sizing can be accomplished by varying the relative channel widths and/or channel lengths of the PMOS and NMOS devices in each invertor. Some examples utilize a fixed channel length and adjust the channel width. For example, for a given fixed channel length such as 0.7 micrometers (μm), the different ratios can be achieved by adjusting the channel widths, illustratively using width/length values and PMOS:NMOS channel size ratios of MP1:MN1=(5/0.7):(1/0.7) and MP2:MN3=(1.8/0.7):(1.8/0.7). Numerous other types of adjustments in channel widths and/or channel lengths can be used in setting the first and second trigger levels provided by the respective first and second trigger circuitry 302 and 304 in other examples.

In some examples, the sizing of the respective PMOS and NMOS devices of an inverter in a ratio of 2:1 or 3:1 will result in a trigger level at approximately 50% of the supply voltage, and adjustments in channel sizing are made relative to such a baseline in order to achieve a trigger level of about 66% of the supply voltage for the first trigger circuitry 302 and about 33% of the supply voltage for the second trigger circuitry 304. Other examples of channel size ratios that can be used to achieve these or similar trigger levels include MP1:MN1 ratios of 4:1 or 6:1, and MP2:MN3 ratios of 1.2:1 or 0.8:1, with the latter example ratio of 0.8:1 indicating that the relative channel sizing is such that NMOS device is relatively stronger than the PMOS device.

In some examples, the above-described adjustments in channel sizing of the first and second inverters of the respective first and second trigger circuitry 302 and 304 are used to set the respective first and second trigger levels VIH and VIL. For example, the first and second trigger levels VIH and VIH may be set to about 0.8V and about 0.4V, respectively, for a VDDIO supply voltage of about 1.2V. The trigger level VIH is set by the relative channel sizing of MP1 and MN1, and the trigger level VIL is set by the relative channel sizing of MP2 and MN3. The hysteresis in such examples is generally given by the difference between the first trigger level VIH and the second trigger level VIL. Other trigger levels and associated amounts of hysteresis can be established in other examples. For example, the trigger level VIH may be set to a value less than 0.8V and the trigger level VIL may be set to a value greater than 0.4V, while VIH remains higher than VIL so as to provide a desired amount of hysteresis given by VIH-VIL, such as at least 50 mV of hysteresis.

The additional PMOS device MP3 of the first trigger circuitry 302 and the additional NMOS device MN5 of the second trigger circuitry 304 illustratively have their respective channel sizes configured in a 2:1 ratio, as such sizing in these additional PMOS and NMOS devices does not significantly impact the trigger levels. However, in some examples, adjustments can made to the relative channel sizing of these devices to make other adjustments in the receiver output Y of the receiver circuit 300, such as adjustment in duty cycle.

As illustrated in FIG. 3, substrate connections for the PMOS and NMOS devices of the first and second trigger circuitry are shown as being coupled to the VDDIO supply terminal or the ground terminal, respectively. Other types of substrate connections can be used in other examples, and such variations can be used to adjust the threshold voltages of the PMOS and NMOS devices.

The receiver circuit 300 is configured to operate with up to a 5V input signal, such as an input signal that varies in voltage level between about zero volts for a logic low level and about 5V for a logic high level. As the input node 301 to which the input signal is applied in such an example can swing between zero volts and 5V, MP1, MN1, MP2 and MN3 are all configured as 5V MOS devices. Other input signal levels and associated PMOS and NMOS device configurations can be used in other examples.

As indicated previously, the latch circuit 305 includes inverters denoted as IN1 and IN2, arranged in series with one another at the common output node OUT, with an input of inverter IN2 being coupled to the outputs of the respective first and second trigger circuitry 302 and 304 at the common output node OUT, an output of inverter IN2 being coupled to an input of inverter IN1, and an output of inverter IN1 being coupled to the outputs of the first and second trigger circuitry 302 and 304 at the common output node OUT. This example arrangement provides what is referred to herein as a “weak” latch, which is a configured to hold the common output node OUT at a particular logic level under a floating condition where the additional PMOS device MP3 of first trigger circuitry 302 turns off before the additional NMOS device MN5 of second trigger circuitry 304 turns on, and vice versa. In the inverters IN1 and IN2 of the latch circuit 305, the channel lengths of the PMOS and NMOS devices are approximately 3 μm, and the ratios of the channel sizes of the respective PMOS and NMOS devices of these inverters, in terms of both widths and lengths, are about (1/3):(3/3) in inverter IN1 and (3/3):(1/3) in inverter IN2, such that IN2 is a weak inverter relative to the inverter IN1, and with the variation in channel size being achieved by adjustment in channel widths for a fixed channel length. Other types and arrangements of inverters or other latch circuitry can be used in the latch circuit 305 in other examples.

The output of the latch circuit 305 is coupled to an input of the inverting level shifter 306. The inverting level shifter 306 is configured to adjust receiver output signal values from levels associated with the VDDIO supply to levels associated with a core voltage supply denoted VCORE, which in some examples may be approximately 1.8V, although other core voltage supply values may be used in other examples. The inverting level shifter 306 is illustratively implemented as a cross-coupled level shifter utilizing techniques such as those disclosed in the above-cited U.S. Pat. No. 10,848,156. As an inverting level shifter 306 is used in this example, the additional inverter IN3 is included at the output of the inverting level shifter 306 to maintain the desired logic levels at the receiver output Y. Other types and arrangements of level shifter circuits can be used in other examples. For example, a non-inverting level shifter may be used in place of inverting level shifter 306, in which case the additional output inverter IN3 may be eliminated.

Additional aspects of the operation of the receiver circuit 300 of FIG. 3 will now be described with reference to FIG. 3 and the example timing diagrams of FIGS. 4 and 5.

Referring now to FIG. 4, an example timing diagram shows respective signals for receiver input PAD, output OUT1 of the upper inverter comprising MP1 and MN1 in first trigger circuitry 302, output OUT2 of the lower inverter comprising MP2 and MN3 in second trigger circuitry 304, common output node OUT and receiver output Y. It is assumed in this example that the VDDIO supply is 1.2V, and that the first and second trigger levels VIH and VIL are 0.8V and 0.4V, respectively. It is further assumed that the receiver input PAD varies from a logic low level of about zero volts to a logic high level of about 5V.

As receiver input PAD makes a low-to-high transition, from its logic low level of about zero volts to its logic high level of about 5V, it crosses 0.4V, at which point output OUT2 of the second inverter switches to a logic low level, turning off MN5. Once PAD crosses the VIH trigger level of 0.8V, output OUT1 of the first inverter switches to a logic low level, turning on MP3 and eventually driving the receiver output Y to a logic high level via the latch circuit 305, the inverting level shifter 306 and the output inverter IN3. Accordingly, the receiver output Y of receiver circuit 300 switches from a logic low level to a logic high level once PAD crosses the VIH trigger level of 0.8V.

As receiver input PAD makes a high-to-low transition, from its logic high level of about 5V to its logic low level of about zero volts, it crosses 0.8V, at which point output OUT1 of the first inverter switches to a logic high level, turning off MP3. Once PAD crosses the VIL trigger level of 0.4V, output OUT2 of the first inverter switches to a logic high level, turning on MN5 and eventually driving the receiver output Y to a logic low level via the latch circuit 305, the inverting level shifter 306 and the output inverter IN3. Accordingly, the receiver output Y of receiver circuit 300 switches from a logic high level to a logic low level once PAD crosses the VIL trigger level of 0.4V.

As indicated previously, the latch circuit 305 is illustratively configured to hold the common output node OUT at a particular logic level under the floating condition where MP3 turns off before MN5, and vice versa. As indicated previously, IN2 is a weak inverter, and the channel sizes of IN1 and IN2 are illustratively configured to ensure that when output OUT1 of the first inverter drops below VDDIO by the PMOS device threshold voltage to turn on MP3, the current through MP3 is much greater than the pull-down current of IN1. Similarly, when output OUT2 of the second inverter reaches the NMOS device threshold voltage to turn on MN5, the current through MN5 is much greater than the pull-up current of IN1.

In the present example, the channel size ratio of MP1:MN1 in the first inverter is illustratively about 5:1 to set the VIH trigger level to about 0.8V and the channel size ratio of MP2:MN3 in the second inverter is illustratively about 1:1 to set the VIL trigger level to about 0.4V. Again, other ratios can be used in other examples. For example, the channel size ratios can be adjusted such that the VIH trigger level is greater than about 0.5*VDDIO and the VIL trigger level is less than about 0.5*VDDIO, with a desired level of hysteresis (e.g., at least 50 mV) being provided by the difference between VIH and VIL.

Referring now to FIG. 5, an example timing diagram illustrates a receiver input signal 501 applied to input node 301 of receiver circuit 300, with a corresponding receiver output signal 502 superimposed over the receiver input signal 501, to more clearly illustrate the first and second trigger levels VIH and VIL established by the respective first and second trigger circuitry 302 and 304. The receiver input signal 501 and the receiver output signal 502 are also denoted as input PAD and output Y. It is assumed in this example that specification values VIH_Spec and VIL_Spec for VIH and VIL are 800 mv (0.8V) and 400 mV (0.4V), respectively, as indicated by horizontal dashed lines 504 and 506 in FIG. 5. For example, a corresponding specification for the receiver circuit 300 may indicate that the receiver circuit provides a VIH trigger level less than about VIH_Spec=0.8V, and a VIL trigger level greater than about VIL_Spec=0.4V, with at least a minimum amount of hysteresis (e.g., 50 mV) for a VDDIO supply voltage of about 1.2V and for receiver input signals with voltage magnitudes of up to about 5V. In this example, the actual value of the VIH trigger level is a value 514 (e.g., about 704 mV) that is less than the VIH specification value VIH_Spec, and the actual value of the VIL trigger level is a value 516 (e.g., about 533 mV) that is greater than the VIL specification value VIL_Spec, with an amount of hysteresis given by the difference between the values 514 and 516 (e.g., about 171 mV), for an input PAD logic high level of about 2V as shown in FIG. 5.

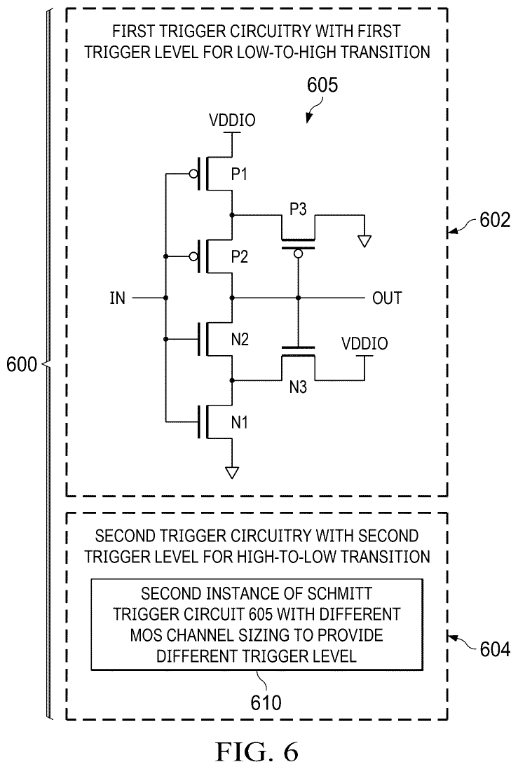

As indicated above, other types and arrangements of first and second trigger circuitry can be used in implementing a receiver circuit as disclosed herein. For example, first and second Schmitt trigger circuits can be used in place of the first and second inverters of the respective first and second trigger circuitry used to set the respective first and second trigger levels for the receiver circuit, as will now be described in more detail with reference to the example of FIG. 6.

FIG. 6 shows a receiver circuit 600 with parallel trigger circuitry comprising first trigger circuitry 602 and second trigger circuitry 604. The receiver circuit 600 may further comprise, in addition to the first trigger circuitry 602 and the second trigger circuitry 604, an input pad, enable circuitry, a latch circuit and a level shifter circuit, with these additional components being arranged as previously described in conjunction with the receiver circuit 100 of FIG. 1, although such additional components are omitted from FIG. 6 for simplicity and clarity of illustration. The operation of the receiver circuit 600 is also generally the same as that of receiver circuit 100 of FIG. 1 as previously described, but in the present example the first trigger circuitry 602 and second trigger circuitry 604 more particularly comprise respective distinct instances of Schmitt trigger circuits. The respective Schmitt trigger circuits of the first and second trigger circuitry 602 and 604 are utilized to set a respective first trigger level (e.g., a VIH level) for a low-to-high transition of an input signal applied to an input pad of the receiver circuit 600 and a second trigger level (e.g., a VIL level) for a high-to-low transition of the input signal applied to the input pad.

As shown in FIG. 6, the first trigger circuitry 602 includes a first Schmitt trigger circuit 605 and the second trigger circuitry 604 comprises a second Schmitt trigger circuit 610. The second Schmitt trigger circuit 610 more particularly comprises a second instance of the first Schmitt trigger circuit 605 but with different MOS channel sizing of one or more MOS devices to provide a different trigger level relative to that provided by the first instance of the Schmitt trigger circuit 605 in first trigger circuitry 602. Accordingly, in the present example, a separate and distinct instance of the Schmitt trigger circuit 605 is illustratively implemented in each of the first trigger circuitry 602 and the second trigger circuitry 604. Each such instance of the Schmitt trigger circuit 605 includes an input node IN, an output node OUT, PMOS devices P1, P2 and P3, and NMOS devices N1, N2 and N3, arranged as illustrated in FIG. 6, with the PMOS and NMOS devices being arranged between a VDDIO supply terminal and a ground terminal as shown. The first instance of the Schmitt trigger circuit 605 in the first trigger circuitry 602 is configured with the first trigger level for the low-to-high transition of the input signal applied to the input pad of the receiver circuit 600, and the second instance of the Schmitt trigger circuit 605 in the second trigger circuitry 604 is configured with the second trigger level for the high-to-low transition of the input signal applied to the input pad of the receiver circuit 600.

In some examples, the two different instances of the Schmitt trigger circuit 605 are adjusted to achieve a trigger level of about 66% of the VDDIO supply voltage for the first trigger circuitry 602 and about 33% of the VDDIO supply voltage for the second trigger circuitry 604, relative to a baseline configuration providing a trigger level at approximately 50% of the VDDIO supply voltage. For example, the trigger level of the first instance of the Schmitt trigger circuit 605 in the first trigger circuitry 602 is established by increasing the channel size ratios of P1 and P2 relative to N1 and N2, and/or by using a relatively larger channel size for N3. Similarly, the trigger level of the second instance of the Schmitt trigger circuit 605 in the second trigger circuitry 604 is established by decreasing the channel size ratios of P1 and P2 relative to N1 and N2, and/or by using a relatively smaller channel size for N3, as compared to the above-noted baseline configuration. The relative channel sizing will vary depending upon factors such as the fabrication technology used, the supply voltage, and the particular VIH and VIL trigger levels and associated amounts of hysteresis desired in a given implementation.

Examples described herein provide receiver circuits configured with separate first and second trigger circuitry, arranged at least in part in parallel with one another, to provide respective VIH and VIL trigger levels. Such receiver circuits can advantageously operate with I/O supply voltages (e.g., 1.2V) that are significantly less than the maximum input signal voltage swing (e.g., 5V), while also providing suitable amounts of hysteresis and drawing negligible static current. As indicated previously, such examples provide technical solutions to significant problems of alternative approaches, by overcoming challenges that can otherwise arise in attempting to configure a receiver circuit to operate at relatively low VDDIO supply voltage levels while also accommodating relatively high input signal swings, and providing desired amounts of hysteresis at low static current.

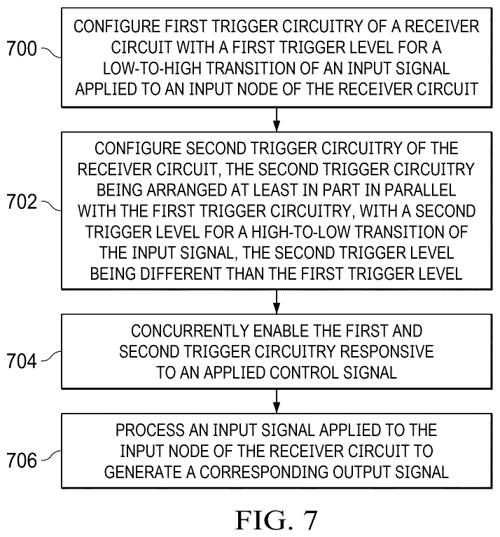

Referring now to FIG. 7, a method of operating a receiver circuit is shown. The method includes steps 700, 702, 704 and 706, which are illustratively performed with reference to the receiver circuit 100 of FIG. 1, although the same or similar steps can be performed relative to other receiver circuits described herein, including receiver circuit 300 of FIG. 3.

In step 700, first trigger circuitry of a receiver circuit is configured with a first trigger level for a low-to-high transition of an input signal applied to an input node of the receiver circuit.

In step 702, second trigger circuitry of the receiver circuit, arranged at least in part in parallel with the first trigger circuitry, is configured with a second trigger level for a high-to-low transition of the input signal, the second trigger level being different than the first trigger level.

Terms such as “configured” and “configuring” as used in this context and other similar contexts herein are intended to be broadly construed, and should not be viewed as implying or requiring any type of user selection or other user-based control of a trigger level of the trigger circuitry. For example, trigger circuitry can be illustratively configured with a particular trigger level as described herein by producing the trigger circuitry as described, obtaining the trigger circuitry as described, and/or activating the trigger circuitry as described at least in part by application of appropriate supply voltages to the trigger circuitry.

In some examples, the configurations of steps 700 and 702 can be performed at least in part by producing, obtaining and/or activating a receiver circuit 100 with first and second trigger circuitry 102 and 104 for respective VIH and VIL trigger levels as previously described.

In step 704, the first and second trigger circuitry is concurrently enabled responsive to an applied control signal. For example, the first and second trigger circuitry can be concurrently enabled by applying the above-described receiver enable signal RXEN to enable circuitry of each of the first and second trigger circuitry of the receiver circuit at an appropriate logic level (e.g., a logic high level in the case of the receiver circuit 300 of FIG. 3).

In step 706, an input signal applied to the input node of the receiver circuit is processed in the receiver circuit to generate a corresponding output signal. For example, a receiver input signal PAD is illustratively processed to generate a receiver output signal Y as illustrated in the timing diagrams of FIGS. 4 and 5.

Although shown in serial order, the steps of the FIG. 7 method and other methods described herein need not be performed in the particular order shown. For example, certain steps may be performed at least in part in parallel with one another, and additional or alternative steps may be used in other examples.

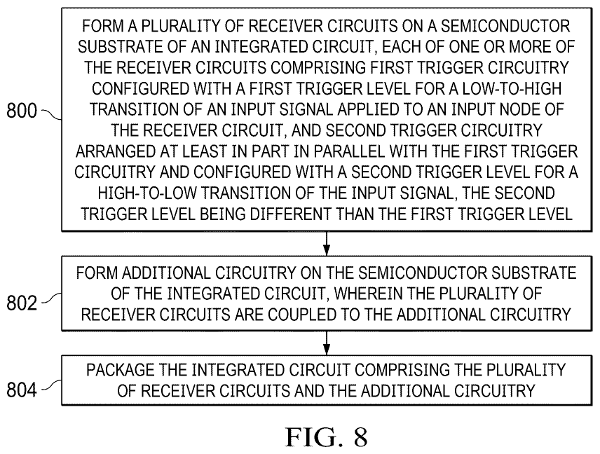

Referring now to FIG. 8, a method of manufacturing an integrated circuit comprising a plurality of receiver circuits is shown. The method includes steps 800, 802 and 804, which are illustratively performed with reference to at least one instance of integrated circuit 200 of FIG. 2, although the same or similar steps can be performed relative to other integrated circuits described herein.

In step 800, receiver circuits are formed on a semiconductor substrate of an integrated circuit. Each of one or more of the receiver circuits comprises first trigger circuitry configured with a first trigger level for a low-to-high transition of an input signal applied to an input node of the receiver circuit, and second trigger circuitry arranged at least in part in parallel with the first trigger circuitry and configured with a second trigger level for a high-to-low transition of the input signal, the second trigger level being different than the first trigger level.

For example, forming the first trigger circuitry illustratively comprises forming respective P-type and N-type field effect transistors of a first inverter of the first trigger circuitry 102 with channel sizes in a first ratio that at least partially sets the first trigger level, and forming the second trigger circuitry comprises forming respective P-type and N-type field effect transistors of a second inverter of the second trigger circuitry 104 with channel sizes in a second ratio, different than the first ratio, that at least partially sets the second trigger level.

In step 802, additional circuitry is formed on the semiconductor substrate of the integrated circuit, with the plurality of receiver circuits being coupled to the additional circuitry. For example, the additional circuitry can comprise power management circuitry 220 and/or other core circuitry 230 as shown in FIG. 2.

Such additional circuitry can be formed at least in part concurrently with the formation of the receiver circuits in step 800. These formation steps illustratively utilize semiconductor process techniques of the type previously described herein.

In step 804, the integrated circuit comprising the plurality of receiver circuits and the additional circuitry is packaged. For example, in the case of multiple integrated circuits formed on a semiconductor wafer, individual integrated circuits are diced from the wafer. The individual integrated circuits are then each subject to additional operations such as lead frame attachment, wire bonding and encapsulation, and then packaged in an appropriate package such as a single in-line package (SIP), dual in-line package (DIP), quad flat no-lead (QFN) package, dual flat no-lead (DFN) package, chip-on-lead (COL) package, etc.

Again, although shown in serial order, the steps of the FIG. 8 method need not be performed in the particular order shown. For example, certain steps, such as the steps 800 and 802 of forming the respective receiver circuits and additional circuitry, may be performed at least in part in parallel with one another, and additional or alternative steps may be used in other examples.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A receiver circuit, comprising:
first trigger circuitry configured with a first trigger level for a low-to-high transition of an input signal applied to an input node of the receiver circuit; and
second trigger circuitry arranged at least in part in parallel with the first trigger circuitry and configured with a second trigger level for a high-to-low transition of the input signal, the second trigger level being different than the first trigger level;
wherein respective inputs of the first and second trigger circuitry are coupled to the input node of the receiver circuit and respective outputs of the first and second trigger circuitry are coupled to an output node of the receiver circuit.

2. The receiver circuit of claim 1, further comprising control circuitry configured to concurrently enable the first and second trigger circuitry responsive to an applied control signal.

3. The receiver circuit of claim 1, wherein the first trigger circuitry is configured to drive the output node of the receiver circuit to one of a logic high level and a logic low level responsive to the low-to-high transition of the input signal and the second trigger circuitry is configured to drive the output node of the receiver circuit to the other of the logic high level and the logic low level responsive to the high-to-low transition of the input signal.

4. The receiver circuit of claim 1, wherein the first and second trigger circuitry comprise respective first and second inverters, each of the first and second inverters having an input coupled to the input node of the receiver circuit and an output coupled to the output node of the receiver circuit.

5. The receiver circuit of claim 4, wherein each of the first and second inverters comprises a first P-type field effect transistor and a first N-type field effect transistor, each having a gate terminal, a source terminal and a drain terminal, the gate terminals being coupled to the input node of the receiver circuit, the source terminal of the first P-type field effect transistor being coupled to an upper supply terminal of the receiver circuit, the drain terminal of the first P-type field effect transistor being coupled to the drain terminal of the first N-type field effect transistor, and the source terminal of the first N-type field effect transistor being coupled to a lower supply terminal of the receiver circuit.

6. The receiver circuit of claim 5, wherein the first trigger circuitry further comprises an additional P-type field effect transistor having a gate terminal coupled to the respective drain terminals of the first P-type field effect transistor and the first N-type field effect transistor of the first inverter, a source terminal coupled to the upper supply terminal, and a drain terminal coupled to the output node of the receiver circuit.

7. The receiver circuit of claim 5, wherein the second trigger circuitry further comprises an additional N-type field effect transistor having a gate terminal coupled to the respective drain terminals of the first P-type field effect transistor and the first N-type field effect transistor of the second inverter, a source terminal coupled to the lower supply terminal, and a drain terminal coupled to the output node of the receiver circuit.

8. The receiver circuit of claim 4, wherein channel sizes of respective P-type and N-type field effect transistors of the first inverter are configured in a first ratio that at least partially sets the first trigger level, and channel sizes of respective P-type and N-type field effect transistors of the second inverter are configured in a second ratio, different than the first ratio, that at least partially sets the second trigger level.

9. The receiver circuit of claim 8, wherein the first ratio is between approximately 4:1 and approximately 6:1 and the second ratio is between approximately 0.8:1 and approximately 1.2:1.

10. The receiver circuit of claim 1, wherein the first and second trigger circuitry comprise respective first and second Schmitt trigger circuits, with the respective first and second trigger levels being configured based at least in part on utilization of different channel sizes for respective corresponding field effect transistors in the first and second Schmitt trigger circuits.

11. The receiver circuit of claim 1, further comprising a level shifter coupled between the outputs of the respective first and second trigger circuitry and the output node of the receiver circuit.

12. The receiver circuit of claim 1, further comprising a latch circuit coupled between the outputs of the respective first and second trigger circuitry and the output node of the receiver circuit.

13. The receiver circuit of claim 12, wherein the latch circuit comprises a serial arrangement of multiple invertors, with an input of a first one of the multiple inverters being coupled to the outputs of the respective first and second trigger circuitry, an output of the first one of the multiple inverters being coupled to an input of another one of the multiple inverters, and an output of the other one of the multiple inverters being coupled to the outputs of the first and second trigger circuitry.

14. The receiver circuit of claim 12, wherein an output of the latch circuit is coupled to an input of a level shifter circuit and an output of the level shifter circuit is coupled to the output node of the receiver circuit.

15. An integrated circuit, comprising:
a plurality of receiver circuits; and
additional circuitry coupled to the plurality of receiver circuits;
wherein at least one of the receiver circuits comprises:
first trigger circuitry configured with a first trigger level for a low-to-high transition of an input signal applied to an input node of the receiver circuit; and
second trigger circuitry arranged at least in part in parallel with the first trigger circuitry and configured with a second trigger level for a high-to-low transition of the input signal, the second trigger level being different than the first trigger level;
wherein respective inputs of the first and second trigger circuitry are coupled to the input node of the receiver circuit and respective outputs of the first and second trigger circuitry are coupled to an output node of the receiver circuit.

16. The integrated circuit of claim 15, wherein the first trigger circuitry is configured to drive the output node of the corresponding receiver circuit to one of a logic high level and a logic low level responsive to the low-to-high transition of the input signal and the second trigger circuitry is configured to drive the output node of the corresponding receiver circuit to the other of the logic high level and the logic low level responsive to the high-to-low transition of the input signal.

17. The integrated circuit of claim 15, wherein the first and second trigger circuitry comprise respective first and second inverters, each of the first and second inverters having an input coupled to the input node of the corresponding receiver circuit and an output coupled to the output node of the corresponding receiver circuit.

18. The integrated circuit of claim 17, wherein channel sizes of respective P-type and N-type field effect transistors of the first inverter are configured in a first ratio that at least partially sets the first trigger level, and channel sizes of respective P-type and N-type field effect transistors of the second inverter are configured in a second ratio, different than the first ratio, that at least partially sets the second trigger level.

19. A method of manufacturing an integrated circuit, comprising:
forming a plurality of receiver circuits; and
forming additional circuitry;
wherein the receiver circuits are coupled to the additional circuitry; and
wherein forming each of one or more of the receiver circuits comprises:
forming first trigger circuitry configured with a first trigger level for a low-to-high transition of an input signal applied to an input node of the receiver circuit;
forming second trigger circuitry arranged at least in part in parallel with the first trigger circuitry and configured with a second trigger level for a high-to-low transition of the input signal, the second trigger level being different than the first trigger level;
wherein respective inputs of the first and second trigger circuitry are coupled to the input node of the receiver circuit, and respective outputs of the first and second trigger circuitry are coupled to an output node of the receiver circuit.

20. The method of claim 19, wherein forming the first trigger circuitry comprises forming respective P-type and N-type field effect transistors of a first inverter of the first trigger circuitry with channel sizes in a first ratio that at least partially sets the first trigger level, and forming the second trigger circuitry comprises forming respective P-type and N-type field effect transistors of a second inverter of the second trigger circuitry with channel sizes in a second ratio, different than the first ratio, that at least partially sets the second trigger level.
